(19) United States
(12) Patent Application Publication
(10) Pub. No.: US 2013/0170279 A9
(43) Pub. Date: Jul. 4, 2013

(54) Current Writing Circuit for a Resistive Memory Cell Arrangement

(71) Applicants: Kejie Huang, Singapore (SG); Yan Hwee Sunny Lua, Singapore (SG); Khoon Siah Arthur Ang, Singapore (SG)

(72) Inventors: Kejie Huang, Singapore (SG); Yan Hwee Sunny Lua, Singapore (SG); Khoon Siah Arthur Ang, Singapore (SG)

(73) Assignee: Agency for Science, Technology and Research

(21) Appl. No.: 13/472,740

(22) Filed: May 16, 2012

Related U.S. Application Data
(60) Provisional application No. 61/488,864, filed on May 23, 2011.

(51) Int. Cl. G11C 11/00

(52) U.S. Cl. 365/148

(57) ABSTRACT

A current writing circuit for a resistive memory cell arrangement is provided. The current writing circuit comprises a first current source; a first reference potential terminal; a first switch configured to switch between the first current source and the first reference potential terminal during a write operation; a second current source; a second reference potential terminal; and a second switch configured to switch between the second reference potential terminal when the first switch is switched to the first current source, and the second current source when the first switch is switched to the first reference potential terminal, during the write operation, wherein the first current source and the second current source are of the same polarity. Further embodiments relate to a memory cell arrangement and a method of writing into a target resistive memory cell of a resistive memory cell arrangement.

This application claims the benefit of priority of U.S. provisional patent application No. 61/488,864, filed 23 May 2011, the content of it being hereby incorporated by reference in its entirety for all purposes.

### FIELD OF THE INVENTIONS

Various embodiments relate to a current writing circuit for a resistive memory cell arrangement, a memory cell arrangement, a method of writing into a target resistive memory cell of a resistive memory cell arrangement, and an address decoder and memory controller for controlling the current writing circuit.

### BACKGROUND OF THE INVENTIONS

Spin transfer torque magnetoresistive random access memory (STT-MRAM) have memory cells, in which each cell consists of a magnetic tunneling junction (MTJ) which is made of a ferromagnetic free layer (FL) and a ferromagnetic reference layer (RL), sandwiching a thin barrier spacer. When the magnetizations of the FL and RL are in parallel (P) directions, the magnetoresistance will be in the low resistance state due to tunneling magnetoresistance effect. However, the magnetoresistance will be in the high resistance state when both the FL and RL are in anti-parallel (AP) configuration. The switching of the magnetization direction of the FL may occur by spin transfer torque effect having an electrical current flowing through the MTJ device. The direction of the magnetization switching may be controlled by the direction of the electrical current flow.

A centralized bidirectional current writing circuit scheme with positive and negative current sources has been proposed for the magnetoresistive memory array. Such a centralized bidirectional writing circuit may result in long and un-equal writing circuitry paths among the MTJ cells in the memory array. This subsequently may affect the writing speed of the magnetoresistive memory. Moreover, the introduction of a negative voltage or current source may add complexity and cost to the fabrication process.

Moreover, the current amplitude to write from the P state to AP state is larger than the AP state to P state, due to the intrinsic MTJ stack design and the backscattering effect of the spin-polarized electrons. This difference results in the asymmetry in the current switching profile. In a fixed single current source, usually one current source with large amplitude will be selected to drive both logic states.

There is therefore a need to provide a writing circuit seeking to address at least the above problems of reducing writing time and reducing in electrical potential in the routing, as well as the over-driving of the MTJ cell that could result for the case when the current amplitude for the writing of the state is lower.

### SUMMARY

According to an embodiment, a current writing circuit for a resistive memory cell arrangement is provided. The resistive memory cell arrangement may have a plurality of resistive memory cells. The current writing circuit may include a first current source; a first reference potential terminal; a first switch configured to switch between the first current source and the first reference potential terminal during a write operation; a second current source; a second reference potential terminal; and a second switch configured to switch between the second reference potential terminal when the first switch is switched to the first current source, and the second current source when the first switch is switched to the first reference potential terminal, during the write operation, wherein the first current source and the second current source are of the same polarity.

According to an embodiment, a memory cell arrangement is provided. The memory cell arrangement may include a plurality of resistive memory cells; and a current writing circuit for the plurality of resistive memory cells, the current writing circuit including: a first current source; a first reference potential terminal; a first switch configured to switch between the first current source and the first reference potential terminal during a write operation; a second current source; a second reference potential terminal; and a second switch configured to switch between the second reference potential terminal when the first switch is switched to the first current source, and the second current source when the first switch is switched to the first reference potential terminal, during the write operation, wherein the first current source and the second current source are of the same polarity.

According to an embodiment, a method of writing into a target resistive memory cell of a resistive memory cell arrangement is provided. The method may include switching between a first current source and a first reference potential terminal to the bit line during a write operation; and switching between a second reference potential terminal when the first current source is coupled to the bit line, and a second current source when the first reference potential terminal is coupled to the bit line, to a source line during the write operation, wherein the first current source and the second current source are of the same polarity.

According to an embodiment, an address decoder and memory controller for controlling a current writing circuit for writing into a target resistive memory cell of a resistive memory cell arrangement is provided. The current writing circuit may include a first current source; a first reference potential terminal; a first switch configured to switch between the first current source and the first reference potential terminal during a write operation; a second current source; a second reference potential terminal; and a second switch configured to switch between the second reference potential terminal when the first switch is switched to the first current source, and the second current source when the first switch is switched to the first reference potential terminal, during the write operation, wherein the first current source and the second current source are of the same polarity.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic block diagram of a current writing circuit, according to various embodiments.

FIG. 2 shows a schematic block diagram of a memory cell arrangement, according to various embodiments.

FIG. 3A shows a schematic drawing of the STT-MRAM array, according to various embodiments.

FIG. 3B shows writing of (i) a logic “0” and (ii) a logic “1” to a magnetic tunneling junction device, respectively, according to various embodiments.

FIG. 3C shows a typical asymmetric trend of the resistance with respect to the electrical current in an MTJ cell.

FIG. 4 shows a flow chart illustrating a method of writing into a target resistive memory cell, according to various embodiments.

FIG. 5 shows a schematic drawing of a unit sub-block of a bidirectional current write circuitry of various embodiments.

FIG. 6 shows an example of writing a logic “1” to the MTJ of FIG. 5, according to various embodiments.

FIG. 7 shows an example of writing a logic “0” to the MTJ of FIG. 5, according to various embodiments.

FIG. 8 shows a schematic drawing of the multiple sub-blocks of a bidirectional current write circuitry, according to various embodiments.

FIG. 9 shows a schematic drawing of the multiple sub-blocks of a bidirectional current write circuitry, according to various embodiments.

FIG. 10 shows an example of sequential writing logic “1” to the sub-blocks of FIG. 9, according to various embodiments.

FIG. 11 shows an example of sequential writing logic “0” to the sub-blocks of FIG. 9, according to various embodiments.

FIG. 12 shows a schematic drawing of the multiple sub-blocks of a bidirectional current write circuitry, according to various embodiments.

FIG. 13 shows an example of sequential writing logic “1” to the sub-blocks of FIG. 12, according to various embodiments.

FIG. 14 shows an example of sequential writing logic “0” to the sub-blocks of FIG. 12, according to various embodiments.

FIG. 15 shows a schematic drawing of the multiple sub-blocks of a bidirectional current write circuitry with two types of current sources of different set amplitudes, according to various embodiments.

FIG. 16 shows a schematic drawing of the multiple sub-blocks of a bidirectional current write circuitry with two types of current sources of different set amplitudes, according to various embodiments.

FIG. 17 shows an example of writing logic “1” to the sub-blocks of FIG. 16, according to various embodiments.

FIG. 18 shows an example of writing logic “0” to the sub-blocks of FIG. 16, according to various embodiments.

FIG. 19 shows a top level floor plan of an exemplary memory bank, according to various embodiments.

### DETAILED DESCRIPTION OF THE INVENTIONS

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

In the context of various embodiments, the phrase “at least substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” as applied to a numeric value encompasses the exact value and a variance of +/−5% of the value.

Various embodiments may provide a current writing circuit (e.g. a bidirectional current writing circuit for non-volatile memory). Various embodiments may further provide a bidirectional current writing CMOS circuit for spin transfer torque magnetoresistive random access memory (STT-MRAM).

Various embodiments may provide a circuitry design to perform bidirectional current writing to the magnetoresistive memory element and magnetic memory. The direction of the current flow may determine the logic state of the magnetoresistive memory element. By having localized write current circuitry of various embodiments to modular memory blocks, the write speed of the magnetoresistive memory may be improved (i.e., having higher writing speed) with shorter writing path and reduction on electrical potential drop parasitic capacitance in the routing as compared to the conventional circuitry with a centralized current source module. Further, the circuit design of various embodiments may be simplified by having a single current source design for bidirectional current writing. The modular circuit and circuits using the modular circuit of various embodiments may advantageously include similar reading/writing environment for each cell; no negative current source/voltage bias; shorter the writing net; reduction in the voltage (potential) drop; increased writing speed; reuse of the bias and address between blocks thus saving area and enabling a more compact circuit design; CMOS design and processes; and new writing circuitry to reduce over-driving of the MTJ cells. Although certain embodiments may result in more foot print, but the advantages of having (i) shorter the writing net to reduce the IR drop and parasitic capacitance and increase the writing speed and (ii) the reuse the bias between blocks to save area more than make up for any potential increase in the foot print.

In some embodiments, one type of current source may be used. In other embodiments, two current sources for each sub-block may be used, and two adjacent sub-blocks may share one current source.

Various embodiments may provide dual current source circuitry design for advanced application. Dual current source circuitry design may be implemented to provide two different writing current amplitudes. The circuit with two different current amplitudes may have additional advantage of avoiding over-driving of the magnetic tunneling junction (MTJ) cells.

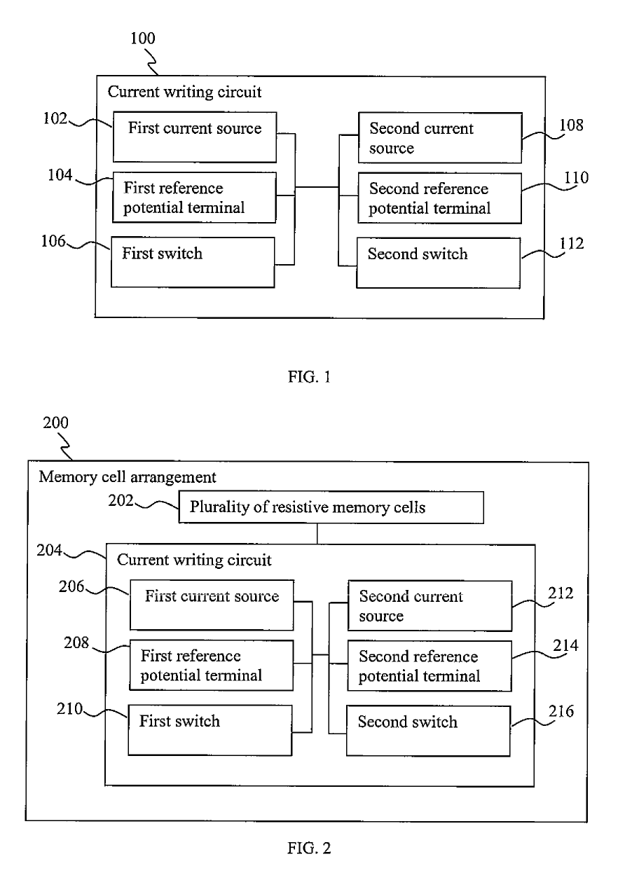

FIG. 1 shows a schematic block diagram of a current writing circuit 100, according to various embodiments. The current writing circuit 100 may include a current writing circuit for a resistive memory cell arrangement, the resistive memory cell arrangement having a plurality of resistive memory cells. The current writing circuit 100 includes a first current source 102; a first reference potential terminal 104; a first switch 106 configured to switch between the first current source 102 and the first reference potential terminal 104 during a write operation; a second current source 108; a second reference potential terminal 110; and a second switch 112 configured to switch between the second reference potential terminal 110 when the first switch 106 is switched to the first current source 102, and the second current source 108 when the first switch 106 is switched to the first reference potential terminal 104, during the write operation, wherein the first current source 102 and the second current source 108 are of the same polarity.

In the context of various embodiments, the term “write operation” refers to an operation where a data bit (i.e., logic ‘1’ or logic ‘0’) is written or stored in the memory cell.

The term “current source” may include, for example, a direct or indirect current source, or a current mirror, or a constant or variable current source, or a voltage bias.

In the context of various embodiments, the first current source 102 may have a current amplitude the same as that of the second current source 108.

In the context of other embodiments, the first current source 102 may have a current amplitude different from that of the second current source 108.

In the context of various embodiments, the first current source 102 and the second current source 108 may be positive current sources. For example, the positive current sources may be in a range of about +0.01 mA to about +1 mA. It should be appreciated that the current source may have any current amplitude suitable to drive the memory cells.

In the context of various embodiments, the first reference potential terminal 104 and the second reference potential terminal 110, each may include a ground potential or about 0 V.

In the context of various embodiments, the current writing circuit 100 may further include a third switch configured to control the write operation to the memory cell.

In the context of various embodiments, the term “control” may refer to enabling or disabling.

In the context of various embodiments, the third switch may be controllable by a word line of the resistive memory cell arrangement. The third switch may be configured to couple in series with the memory cell between a bit line and a source line, and to switch between a low impedance to enable the write operation and a high impedance to disable the write operation.

In the context of various embodiments, the term “in series” may refer to being arranged one after another to form a line, consecutively or non-consecutively.

In the context of various embodiments, the first switch 106 may include a pair of transistors respectively including a source terminal, a drain terminal and a gate terminal. The transistor may be, for example, a field-effect transistor or a metal-oxide-semiconductor field-effect transistor.

In the context of various embodiments, the second switch 112 may include a pair of transistors respectively including a source terminal, a drain terminal and a gate terminal.

In the context of various embodiments, for the first switch 106, the drain terminals of the transistors are configured to couple to a bit line, the source terminal of one of the transistors is coupled to the first reference potential terminal 104, and the source terminal of the other of the transistors is coupled to the first current source 102

In the context of various embodiments, for the second switch 112, the drain terminals of the transistors are configured to couple to a source line, the source terminal of one of the transistors is coupled to the second reference potential terminal 110, and the source terminal of the other of the transistors is coupled to the second current source 108.

In the context of various embodiments, at least one transistor of the pair of transistors may include a complementary-symmetry metal-oxide-semiconductor (CMOS) transistor. In some embodiments, the pair of transistors may include two CMOS transistors. For example, the pair of transistors for the first switch 106 may include two CMOS transistors. In various embodiments, the pair of transistors for the second switch 112 may include two CMOS transistors.

In an embodiment, the pair of transistors for the first switch 106 may be a n-channel MOS transistor and a p-channel MOS transistor.

In another embodiment, the pair of transistors for the second switch 112 may be a n-channel MOS transistor and a p-channel MOS transistor.

In the context of various embodiments, the current writing circuit 100 may include a plurality of first switches and second switches configured to respectively couple to a plurality of bit lines and source lines.

The plurality of bit lines and/or source lines may refer to data lines of the memory cell arrangement. For example, data may be sensed either at a bit line or at a source line.

FIG. 2 shows a schematic block diagram of a memory cell arrangement 200, according to various embodiments. The memory cell arrangement 200 includes a plurality of resistive memory cells 202; and a current writing circuit 204 for the plurality of resistive memory cells 202. The current writing circuit 204 may include a first current source 206; a first reference potential terminal 208; a first switch 210 configured to switch between the first current source 206 and the first reference potential terminal 208 during a write operation; a second current source 212; a second reference potential terminal 214; and a second switch 216 configured to switch between the second reference potential terminal 214 when the first switch 210 is switched to the first current source 206, and the second current source 212 when the first switch 210 is switched to the first reference potential terminal 208, during the write operation, wherein the first current source 206 and the second current source 212 are of the same polarity.

In the context of various embodiments, the term “memory cell arrangement” may be interchangably referred to as “memory” or “memory device”.

In the context of various embodiments, the term “resistive memory cell” is used to describe a memory cell of any kind which can be switched between two or more states exhibiting different electrical resistance values.

In the context of various embodiments, the resistive memory cells 202 may include magnetoresistive memory cells. The resistive memory cells may also be but are not limited to resistive random-access memory (RRAM) (such as for example a phase change memory random-access memory (PCRAM) or conductive bridging random-access memory (CBRAM)) or magnetoresistive random-access memory (MRAM) or redox-based resistive switching memories.

For example, the magnetoresistive memory cells may include a spin transfer torque magnetoresistive random access memory (STT-MRAM).

In various embodiments, the current writing circuit 204 of FIG. 2 may be the current writing circuit 100 of FIG. 1. The first current source 206, the first reference potential terminal 208, the first switch 210, the second current source 212; the second reference potential terminal 214; and the second switch 216 of FIG. 2 may be the first current source 102, the first reference potential terminal 104, the first switch 106, the second current source 108; the second reference potential terminal 110; and the second switch 112 of FIG. 1, respectively.

The terms “current source” and “write operation” are as defined hereinabove.

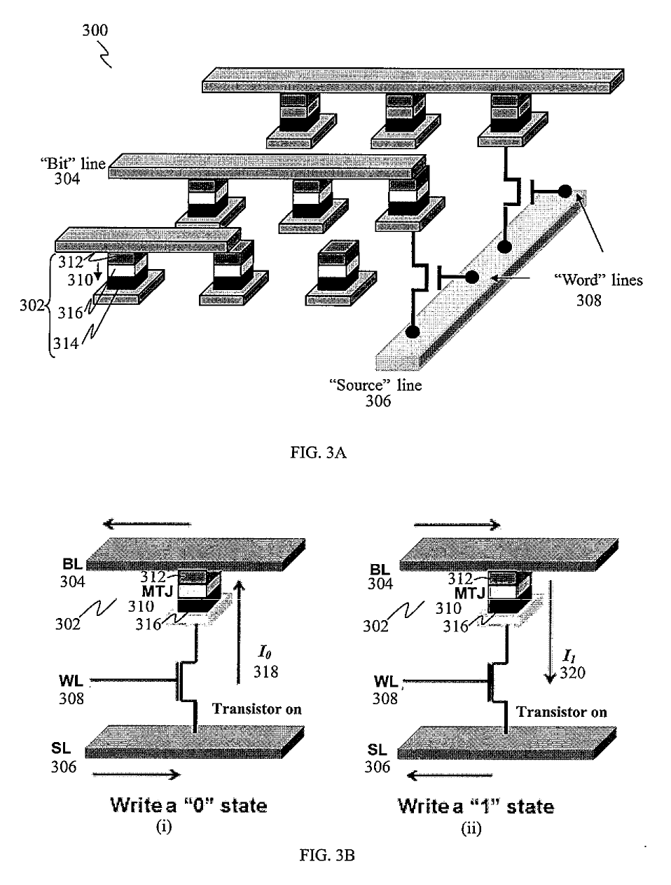

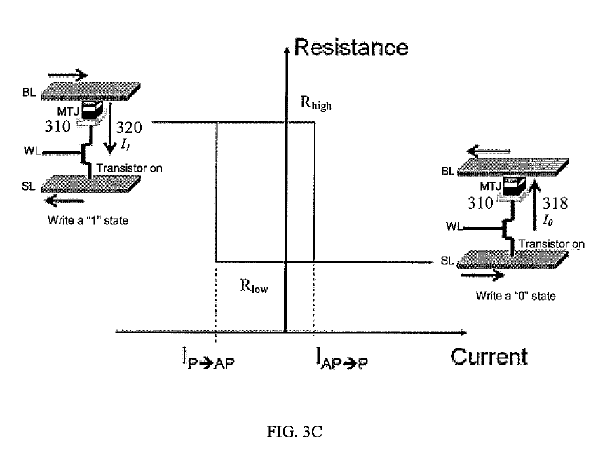

FIG. 3A shows an exemplary spin transfer torque magnetoresistive random access memory (STT-MRAM) 400, in accordance to various embodiments.

STT-MRAM may be considered as a promising candidate for the next generation of non-volatile memory as it possesses the advantages of scalability, high endurance, high speed and low energy consumption. In FIG. 3A, the STT-MRAM may include a plurality or an array of STT-MRAM cells, for example, STT-MRAM cell 302, a plurality of bit lines (BL) 304, a plurality of source lines (SL) 306, and a plurality of word lines (WL) 308. The STT-MRAM cell 302 may include a magnetic tunneling junction (MTJ) 310 which is made of a ferromagnetic free layer (FL) 312 and a ferromagnetic reference layer (RL) 314, sandwiching a thin barrier spacer 316.

FIG. 3B shows two types of schemes in the STT-MRAM cell 302, namely, (i) in-plane and (ii) perpendicular STT-MRAM. The differences lie on the directions of the magnetization direction of the FL 312 and RL 314. For the in-plane STT-MRAM as shown in FIG. 3B(i), the magnetizations of the FL 312 and RL 314 are lying along the in-plane direction. For the perpendicular STT-MRAM as shown in FIG. 3B(ii), the magnetizations of the FL 312 and RL 314 are lying along the out-of-plane direction. When the magnetizations of the FL 312 and RL 314 are in parallel (P) (or in-plane) directions, the magnetoresistance is of a low resistance state due to tunneling magnetoresistance effect. The magnetoresistance is of a high resistance state when both the FL 312 and RL 314 are in an anti-parallel (AP) configuration (or out-of-plane directions). The switching of the magnetization direction of the FL 312 may occur by spin transfer torque effect, having an electrical current flowing 318, 320 through the MTJ device. The direction of the magnetization switching may be controlled by the direction of the electrical current flow 318, 320.

FIG. 3C shows a write current source, for example, the current writing source 100, 204 (in FIGS. 1 and 2) designed to have common amplitude to be used for writing of the MTJ 310 to two different logic states as seen in FIGS. 3B(i) and 3B(ii) respectively. From the plot in FIG. 3C, it is observed that the current 318 required for writing an AP state to P state is lower than the case for the P state to AP state (current 320). Hence, if a common current amplitude were used, it would mean that the instance in which there is a writing of an AP state to P state, the MTJ cell may be over-driven.

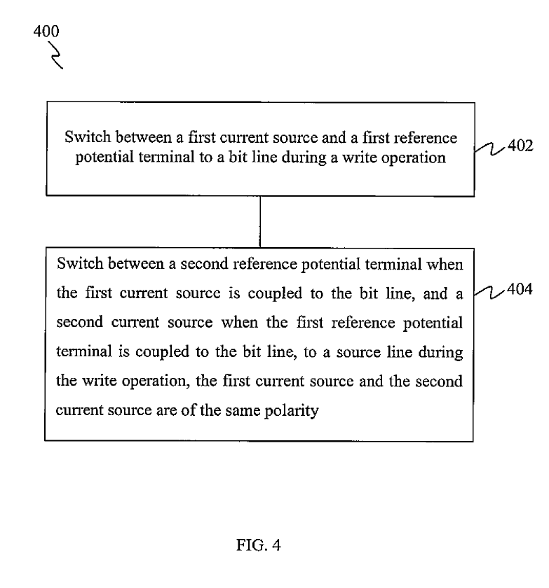

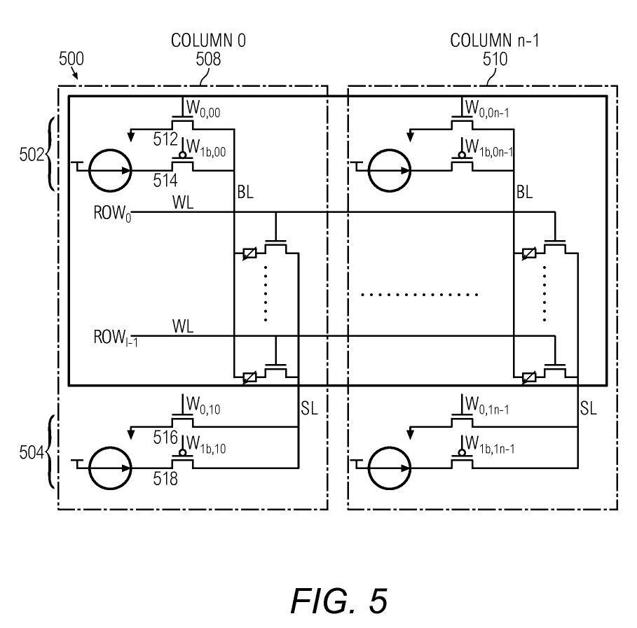

FIG. 4 shows a flow chart 400 illustrating a method of writing into a target resistive memory cell (e.g. the resistive memory cell 202 of FIG. 2) of a resistive memory cell arrangement (e.g. the memory cell arrangement 200 of FIG. 2), according to various embodiments.

At 402, a bit line is switched between a first current source and a first reference potential terminal during a write operation.

At 404, a source line is switched between a second reference potential terminal when the first current source is coupled to the bit line, and a second current source when the first reference potential terminal is coupled to the bit line, during the write operation.

At 402, 404, the first current source and the second current source are of the same polarity.

In the context of various embodiments, the term “resistive memory cell”, “resistive memory cell arrangement”, “current source”, and “write operation” are as defined hereinabove.

In various embodiments, the method may further include controlling the write operation to the resistive memory cell by a word line of the resistive memory cell arrangement.

In various embodiments, the resistive memory cell arrangement may include a plurality of resistive memory cells, and writing into each target resistive memory cell may be performed sequentially.

In this context of various embodiments, the first current source, the first reference potential terminal, the first switch, the second current source, the second reference potential terminal, and the second switch may refer to the first current source 102, 206; the first reference potential terminal 104, 208; the first switch 106, 210; the second current source 108, 212; the second reference potential terminal 110, 214; and the second switch 112, 216 of FIGS. 1 and 2, respectively.

Various embodiments provides a computer readable storage medium having a program with a program code for controlling the current writing circuit by performing the steps of the method as described hereinabove. As used herein, the term “program” refers to the full breadth of its ordinary meaning. For example, the program may be a software program stored in a memory and executable by a processor (e.g., a computer's processor (CPU) or a controller's processor), or a hardware configuration program using programmable hardware elements.

Various embodiments provides an address decoder and memory controller for controlling the current writing circuit. The current writing circuit is for writing into a target resistive memory cell of a resistive memory cell arrangement when the program runs on a processor, the current writing circuit including a first current source; a first reference potential terminal; a first switch configured to switch between the first current source and the first reference potential terminal during a write operation; a second current source; a second reference potential terminal; and a second switch configured to switch between the second reference potential terminal when the first switch is switched to the first current source, and the second current source when the first switch is switched to the first reference potential terminal, during the write operation, wherein the first current source and the second current source are of the same polarity.

In the context of various embodiments, the term “resistive memory cell”, “resistive memory cell arrangement”, “current source”, “write operation”, and “controlling” are as defined hereinabove.

In the context of various embodiments, In this context of various embodiments, the first current source, the first reference potential terminal, the first switch, the second current source, the second reference potential terminal, and the second switch may refer to the first current source 102, 206; the first reference potential terminal 104, 208; the first switch 106, 210; the second current source 108, 212; the second reference potential terminal 110, 214; and the second switch 112, 216 of FIGS. 1 and 2, respectively.

In various embodiments, a set of dedicated bidirectional write current CMOS circuitry to the memory module. FIG. 5 shows a schematic circuit diagram of a bidirectional writing circuit 500, according to various embodiments. In FIG. 5, there are two sets of dedicated current source and ground terminals 502, 504, one at each end of a unit block 506 of memory for each column (e.g. Column 0 508; Column n-1 510 where n represents the total number of columns in the memory cell arrangement).

In the context of various embodiments, the current source and the ground terminal in the first set 502 may refer to the first current source 102, 206 and the first reference potential terminal 104, 208 of FIGS. 1 and 2, respectively. The current source and the ground terminal in the second set 504 may refer to the second current source 108, 212 and the second reference potential terminal 110, 214 of FIGS. 1 and 2, respectively. The transistors 512, 514 may refer to the first switch 106, 210 of FIGS. 1 and 2; and the transistors 516, 518 may refer to the second switch 112, 216 of FIGS. 1 and 2.

Instead of having centralized current sources, there are dedicated localized current sources and grounds to shorten the writing path to each MTJ cells. This is advantageous as the there is less potential drop with a shorter writing path. In addition, as for example in FIG. 5, there is one positive current source design for bidirectional writing, the design is simplified and may be reused. Moreover, positive current source design employed may reduce complexity and cost in manufacturing, thus at least minimizing or overcoming the complexity and fabrication cost when a negative voltage bias or current source is involved. Furthermore, the current source may, for example, be designed to take one fixed current amplitude and pulse width, or have programmable pulse amplitude and pulse duration. Even though current sources are mentioned herein, the design scheme may also be implemented with voltage bias as an alternative, with slight modification. As can be seen in FIG. 5, the circuits are placed at two sides and no additional circuits are at the middle of the blocks.

Transistors may be used as switches to direct the current flow as seen in FIG. 5.

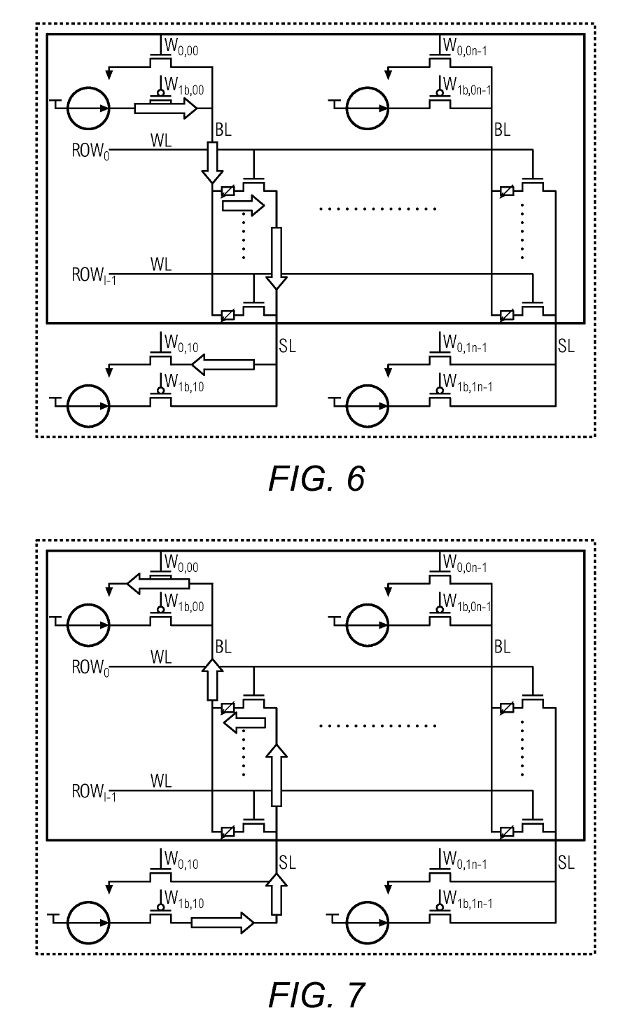

For example in FIG. 6, to write a logic “1” to the MTJ in the top left-hand column, the row 0 word line (WL₀) for the MTJ is set high and the select transistor is switched on. With other transistors switched off and only transistors W_{1b,00} and W_{0,10} of the write current circuitry are switched on, the current pulse will be injected and flow from the top into the bit line, through the MTJ and the select transistor and closes the loop at the ground terminal next to the transistor W_{0,10}. In other words, W_{0,00}=0; W_{1b,00}=0; W_{0,10}=1; and W_{1b,10}=1, a logic ‘1’ is written into the MRAM cells.

By spin transfer torque effect, the magnetization of the FL is switched to be in an AP state (high resistance).

Similarly as an example of FIG. 7, to write a “0” to the same MTJ at row 0 and column 0, the WL is set high to activate the select transistor. Transistors W_{1b,10} and W_{0,00} of the bottom and top write current circuitry are switched on respectively, while the rest of the transistors are switched off.

In this case, the current pulse generated flows in an opposite direction (bottom to top) into the MTJ cell to switch the magnetization of the FL to a P state (low resistance).

In other words W_{0,00}=1; W_{1b,00}=1; W_{0,10}=0; and W_{1b,10}=0, a logic ‘0’ is written into the MRAM cells.

It should be appreciated that although the directions of the current flow defined above are described for the respective logic states, the direction of the current flow may be redefined depending on the pre-defined magnetic orientation of the RL.

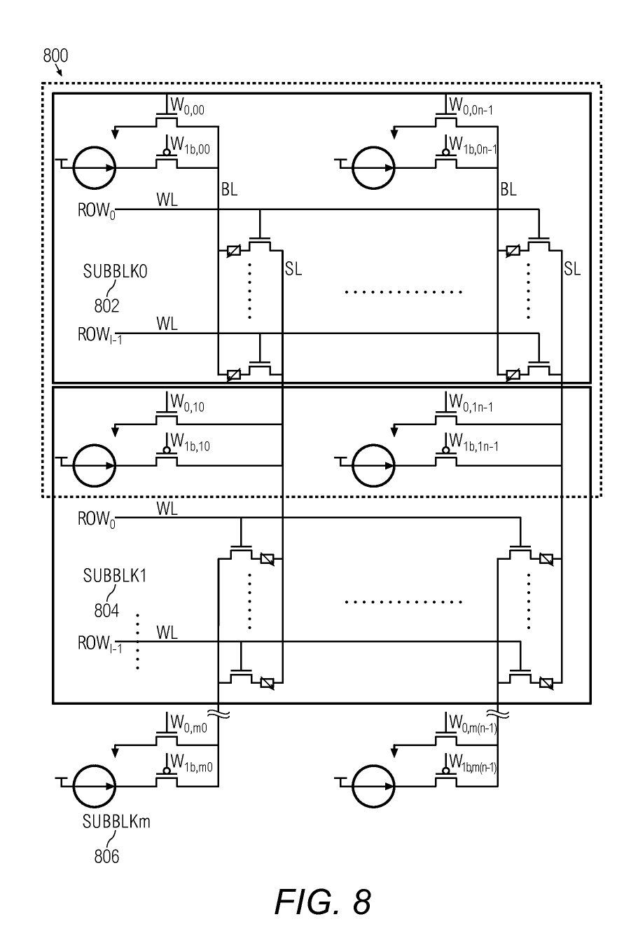

In one embodiment as shown in FIG. 8, the circuit 800 may be further extended to modularize the unit block to many sub-blocks 802, 804, 806 to further reduce the writing paths to each MTJ cells along the column direction. By having the memory array broken down into many sub-blocks 802, 804, 806, the different MTJ cells in each sub-block 802, 804 may be written as described above, but in a sequential fashion.

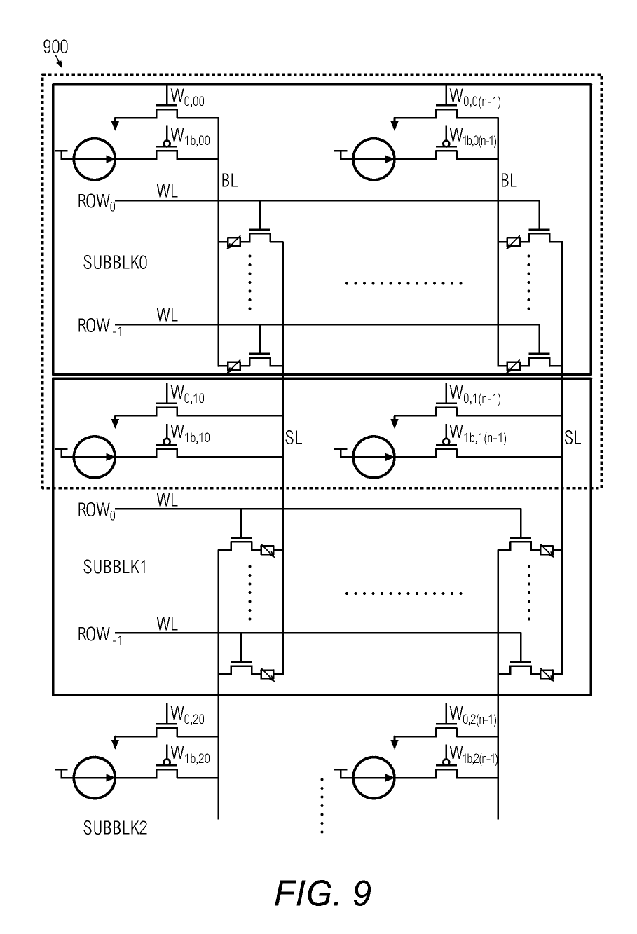

FIG. 9 shows an exemplary circuit 900 having three sub-blocks, in accordance to various embodiments.

The pseudo code for the writing scheme for the circuitry in FIG. 9 is as follows:

Write data to block i, column j:
W_{0,ij}=WE&COLⱼ&BLKᵢ&!D
W_{1b,ij}=!(WE&COLⱼ&BLKᵢ&D)
W_{0,(i+1)j}WE&COLⱼ&BLKᵢ₊₁&D
W_{1b,(i+1)j}=!(WE&COLⱼ&BLKᵢ₊₁&!D)
0 <= i <= m−1
0 <= j <= n−1
Total Size of the block: l*m*n

TABLE 1
List of annotation for the signal used in the pseudo-code.

| Signal | Description |
|---|---|
| W_{0,ij}/W_{1b, ij} | Bidirectional Writing |
| | Control Signal |
| WE | Write Enable Signal |
| COLⱼ | Column Selecting Address |
| BLKᵢ | Block Selecting Signal |
| D | Data to be Written into the |
| | MTJ |
| ROW₁ | ROW Selecting Signal |

Based on the pseudo code for the writing scheme for the circuitry in FIG. 9, to write data to block i, column j, the Bidirectional Writing Control Signal W_{0,ij} is determined by the combination of WE and COLⱼ and BLKᵢ and the inverse of D. That is, W_{0,ij} will be enabled (i.e., having a logic “1”) only when the Write Enable Signal (WE), the Column Selecting Address (COLⱼ) and the Block Selecting Signal (BLKᵢ) are all enabled (i.e., having a logic “1”), while the Data to be Written into the MTJ (D) is logic “0”. For all other combinations, W_{0,ij} will be disabled (i.e., having a logic “0”).

The Bidirectional Writing Control Signal W_{1b,ij} is determined by the inverse of the combination of WE and COLⱼ and BLKᵢ and D. That is, W_{1b,ij} will be disabled (i.e., having a logic “1”) only when at least one of the Write Enable Signal (WE), the Column Selecting Address (COLⱼ), the Block Selecting Signal (BLKᵢ) are disabled (i.e., having a logic “0”), or the Data to be Written into the MTJ (D) is logic “0”. Only when all of the Write Enable Signal (WE), the Column Selecting Address (COLⱼ), the Block Selecting Signal (BLKᵢ) and the Data to be Written into the MTJ (D) are enabled (i.e., having a logic “1”), W_{1b,ij} will be enabled (i.e., having a logic “0”).

The Bidirectional Writing Control Signal W_{0,(i+1)j} is determined by the combination of WE and COLⱼ and BLKᵢ₊₁ and D. That is, W_{0,(i+1)j} will be enabled (i.e., having a logic “1”) only when the Write Enable Signal (WE), the Column Selecting Address (COLⱼ) and the Block Selecting Signal (BLKᵢ₊₁) are all enabled (i.e., having a logic “1”), and the Data to be Written into the MTJ (D) is logic “1”. For all other combinations, W_{0,(i+1)j} will be disabled (i.e., having a logic “0”).

The Bidirectional Writing Control Signal W_{1b,(i+1)j} is determined by the inverse of the combination of WE and COLⱼ and BLKᵢ₊₁ and the inverse of D. That is, W_{1b,(i+1)j} will be disabled (i.e., having a logic “1”) only when at least one of the Write Enable Signal (WE), the Column Selecting Address (COLⱼ), and the Block Selecting Signal (BLKᵢ₊₁) are disabled (i.e., having a logic “0”) or the Data to be Written into the MTJ (D) is a logic “1”. Only when all of the Write Enable Signal (WE), the Column Selecting Address (COLⱼ), the Block Selecting Signal (BLKᵢ₊₁) are enabled (i.e., having a logic “1”) and the Data to be Written into the MTJ (D) is a logic “0”), W_{1b,(i+1)j} will be enabled (i.e., having a logic “0”).

The total size of the block is given by the row number (1) in one sub-block by the total number of sub-blocks (m) by the total number of column (n).

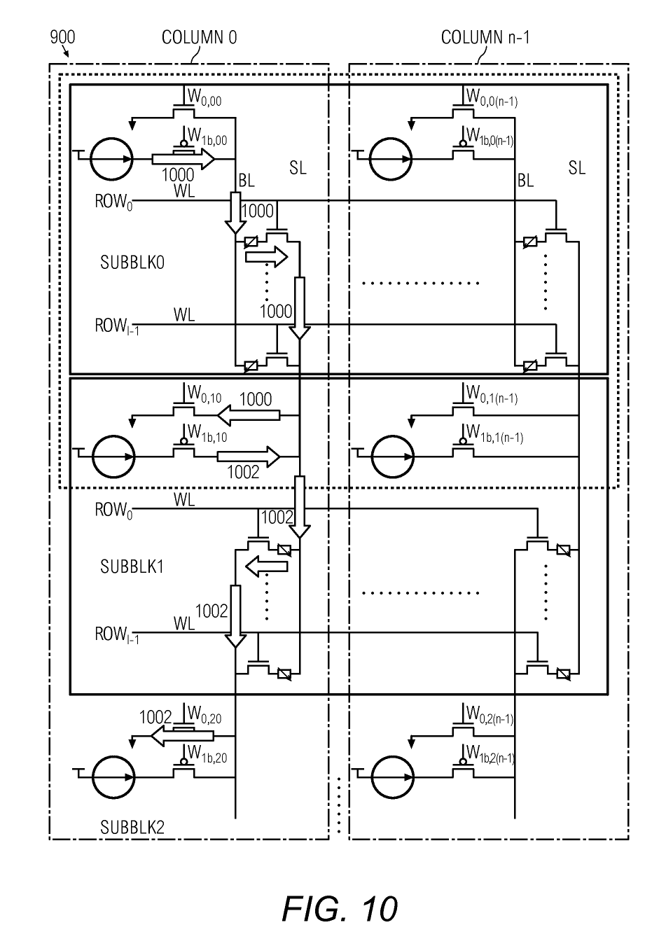

FIG. 10 shows an example of writing two “1”s to two MTJ cells located at row 0 column 0 of sub-blocks 0 and 1 based on the pseudo code for the writing scheme for the exemplary circuit 900 in FIG. 9.

In FIG. 10, the select transistor of sub-block 0 is switched on by the WL. The transistors W_{1b,00} and W_{0,10} of the write current circuitry in sub-block 0 are switched on while the rest of the transistors are switched off, and current pulse is injected into the MTJ cell. Sequentially, the select transistor of row 0 column 0 of sub-block 0 is turned off followed by the switching on the select transistor in row 0 column 0 of sub-block 1. The transistors W_{1b,10} and W_{0,20} of the write current circuitry in sub-block 1 are switched on while the rest of the transistors are switched off. The current pulse is then injected into the MTJ cells located at row 0 column 0 of sub-block 1. This sequential writing scheme may be performed for the writing of different logic states in the MTJ cells by directing the current flow direction.

In other words, lines 1000 shows the writing of logic ‘1’ to sub-block 0, when W_{0,00}=0; W_{1b,00}=0; W_{0,10}=1; and W_{1b,10}=1. Lines 1002 shows the writing of logic ‘1’ to sub-block 1, when W_{0,10}=0; W_{1b,10}=; W_{0,20}=1; and W_{1b,20}=1.

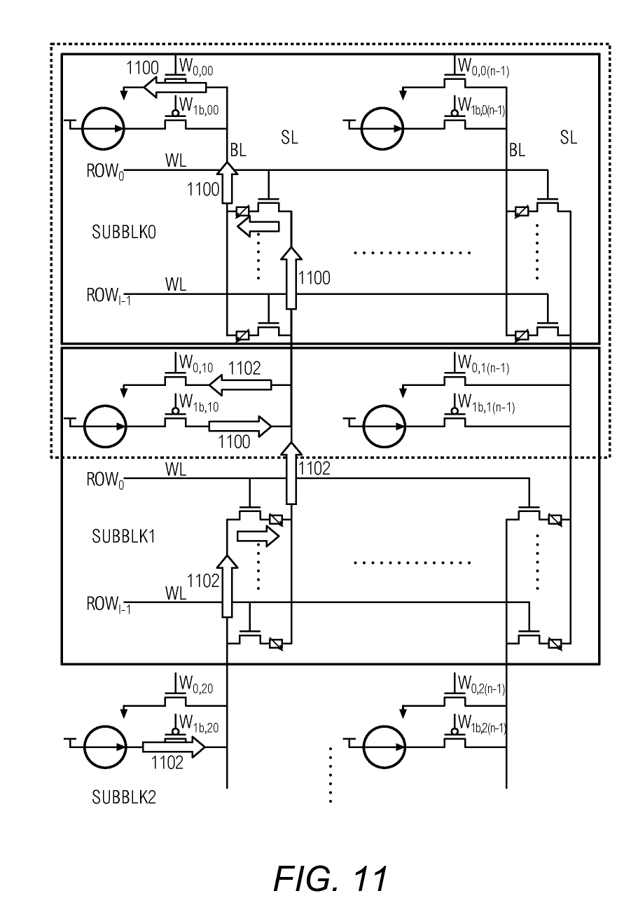

FIG. 11 shows an example of writing two “0”s to two MTJ cells located at row 0 column 0 of sub-blocks 0 and 1 based on the pseudo code for the writing scheme for the exemplary circuit 900 in FIG. 9.

Lines 1100 shows the writing of logic ‘0’ to sub-block 0, when W_{0,00}=1; W_{1b,00}=1; W_{0,10}=0; and W_{1b,10}=0. Lines 1102 shows the writing of logic ‘0’ to sub-block 1, when W_{0,10}=1; W_{1b,10}=1; W_{0,20}=0; and W_{1b,20}=0.

Sub-block 0 and sub-block 1 share the current source and column address at the middle as seen in FIGS. 10 and 11.

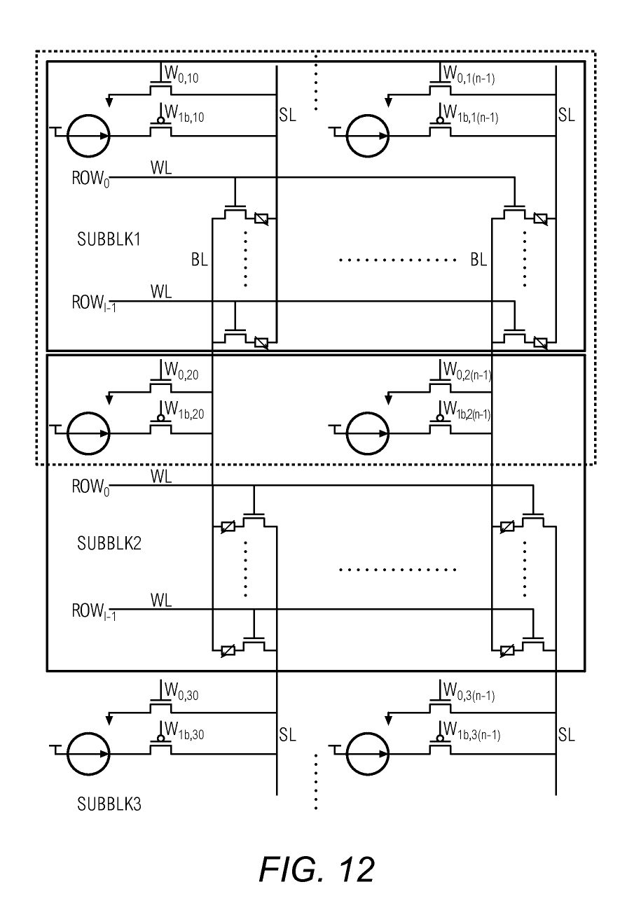

As a further example, FIG. 12 shows the subsequent sub-blocks 1, 2, 3 with respect to FIG. 9, in accordance to various embodiments.

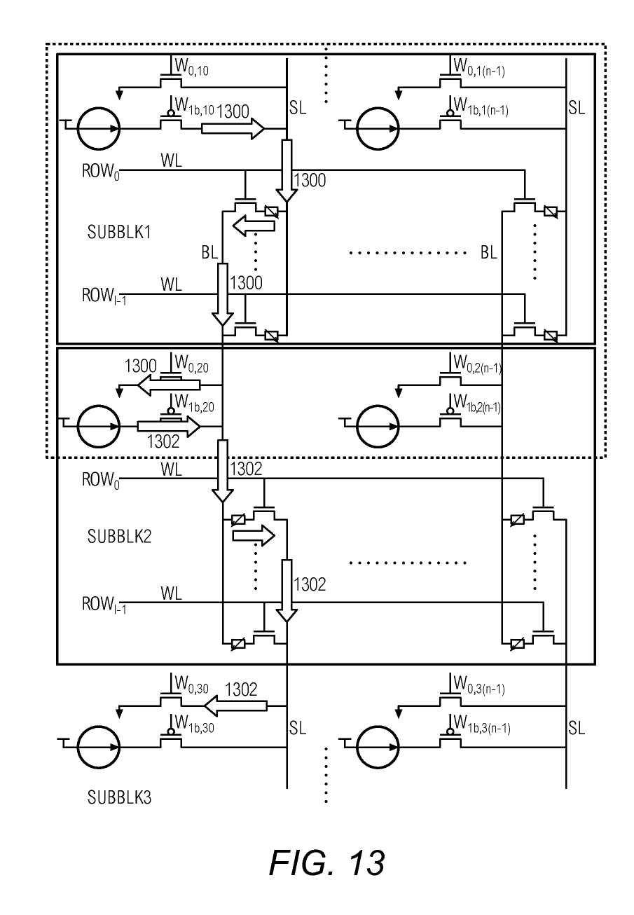

FIG. 13 shows an example of writing two “1”s to sub-blocks 1 and 2 of FIG. 12.

Lines 1300 shows the writing of logic ‘1’ to sub-block 1, when W_{0,10}=0; W_{1b,10}=0; W_{0,20}=1; and W_{1b,20}=1. Lines 1302 shows the writing of logic ‘1’ to sub-block 2, when W_{0,20}=0; W_{1b,20}=0; W_{0,30}=1; and W_{1b,30}=1.

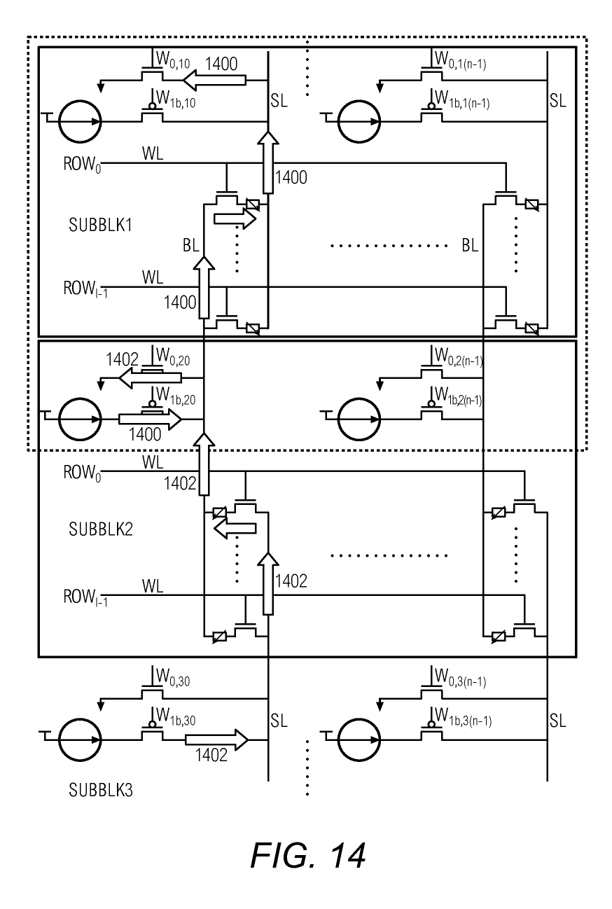

FIG. 14 shows an example of writing two “0”s to sub-blocks 1 and 2 of FIG. 12.

Lines 1400 shows the writing of logic ‘0’ to sub-block 1, when W_{0,10}=1; W_{1b,10}=1; W_{0,20}=0; and W_{1b,20}=0. Lines 1402 shows the writing of logic ‘0’ to sub-block 2, when W_{0,20}=1; W_{1b,20}=1 W_{0,30}=0; and W_{1b,30}=0.

Sub-block 1 and sub-block 2 share the current source and column address at the middle as seen in FIGS. 13 and 14.

As seen in FIGS. 9 to 14, the writing speed may be enhanced since the writing path is shortened and lesser electrical potential drop along the path and parasitic capacitor on bit line and source line. With the modular design, the adjacent sub-blocks may share the column decoder, current source and sense amplifier circuits. This advantageously saves in the design areas by reusing a row of write current circuitry and a column address. Thus, the memory array may be broken down into smaller sub-blocks to adopt for bigger the memory size and higher writing speed requirements.

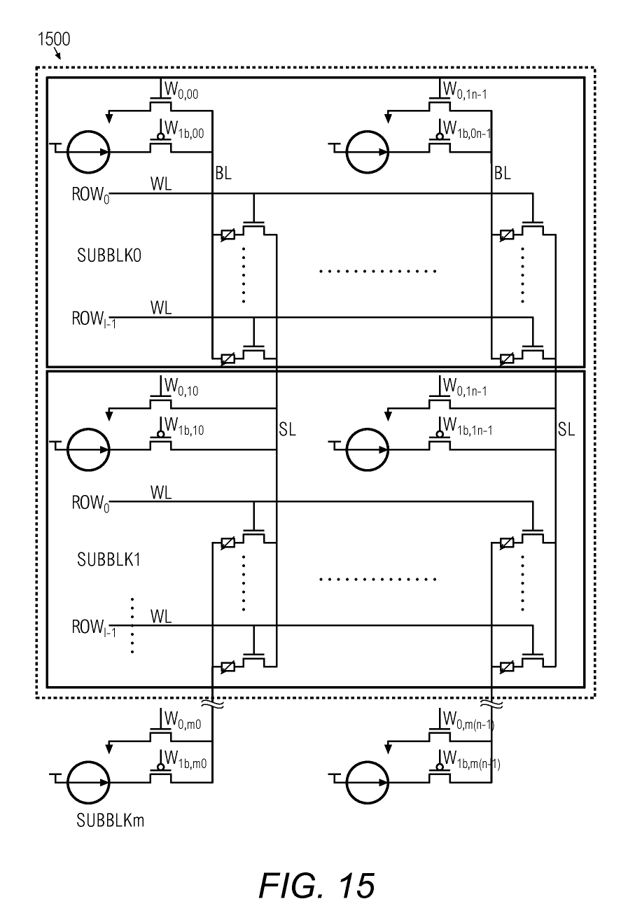

FIG. 15 illustrates the alternative design 1500 to the bidirectional current write circuitry for multiple sub-blocks to include two different writing current amplitudes.

The pseudo code for the writing scheme for the circuitry in FIG. 15 is as follows:

Write data to subblock 2i, column j:
W_{0,2ij}=WE&COLⱼ&BLK₂ᵢ&!D
W_{1b,2ij}=!(WE&COLj&BLK₂ᵢ&D)
W_{0,(2i+1)j}=WE&COLⱼ&BLK₂ᵢ₊₁&D
W_{1b,(2i+1)j}=!(WE&COLⱼ&BLK₂ᵢ₊₁&!D)
Write data to subblock 2i+1, column j:
W_{0,(2i+1)j}=WE&COLⱼ&BLK₂ᵢ₊₁&D
W_{1b,(2i+1)j}=!(WE&COLⱼ&BLK₂ᵢ₊₁&!D)
W_{0,(2i+2)j}=WE&COLⱼ&BLK₂ᵢ₊₂&!D
W_{1b,(2i+2)j}=!(WE&COLⱼ&BLK₂ᵢ₊₂&D)
0 <= 2i <= m−2
0 <= j <= n−1
Total Size of the block: l*m*n

The annotation for the signal used in the pseudo-code is as defined in Table 1.

Based on the pseudo code for the writing scheme for the circuitry in FIG. 15, to write data to subblock 2i, column j, the Bidirectional Writing Control Signal W_{0,2ij} is determined by the combination of WE and COLⱼ and BLK₂ᵢ and the inverse of D. That is, W_{0,2ij} will be enabled (i.e., having a logic “1”) only when the Write Enable Signal (WE), the Column Selecting Address (COLⱼ) and the Block Selecting Signal (BLK₂ᵢ) are all enabled (i.e., having a logic “1”), while the Data to be Written into the MTJ (D) is logic “0”. For all other combinations, W_{0,2ij} will be disabled (i.e., having a logic “0”).

The Bidirectional Writing Control Signal W_{1b,2ij} is determined by the inverse of the combination of WE and COLⱼ and BLK₂ᵢ and D. That is, W_{1b,2ij} will be disabled (i.e., having a logic “1”) only when at least one of the Write Enable Signal (WE), the Column Selecting Address (COLⱼ), the Block Selecting Signal (BLK₂ᵢ) are disabled (i.e., having a logic “0”), or the Data to be Written into the MTJ (D) is logic “0”. Only when all of the Write Enable Signal (WE), the Column Selecting Address (COLⱼ), the Block Selecting Signal (BLK₂ᵢ) and the Data to be Written into the MTJ (D) are enabled (i.e., having a logic “1”), W_{1b,2ij} will be enabled (i.e., having a logic “0”).

The Bidirectional Writing Control Signal W_{0,(2i+1)j} is determined by the combination of WE and COLⱼ and BLK₂ᵢ₊₁ and D. That is, W_{0,(2i+1)j} will be enabled (i.e., having a logic “1”) only when the Write Enable Signal (WE), the Column Selecting Address (COLⱼ) and the Block Selecting Signal (BLK₂ᵢ₊₁) are all enabled (i.e., having a logic “1”), and the Data to be Written into the MTJ (D) is logic “1”. For all other combinations, W_{0,(2i+1)j} will be disabled (i.e., having a logic “0”).

The Bidirectional Writing Control Signal W_{1b,(2i+1)j} is determined by the inverse of the combination of WE and COLⱼ and BLK₂ᵢ₊₁ and the inverse of D. That is, W_{1b,(2i+1)j} will be disabled (i.e., having a logic “1”) only when at least one of the Write Enable Signal (WE), the Column Selecting Address (COLⱼ), and the Block Selecting Signal (BLK₂ᵢ₊₁) are disabled (i.e., having a logic “0”) or the Data to be Written into the MTJ (D) is a logic “1”. Only when all of the Write Enable Signal (WE), the Column Selecting Address (COLⱼ), the Block Selecting Signal (BLK₂ᵢ₊₁) are enabled (i.e., having a logic “1”) and the Data to be Written into the MTJ (D) is a logic “0”), W_{1b,(2i+1)j} will be enabled (i.e., having a logic “0”).

To write data to subblock 2i+1, column j, the Bidirectional Writing Control Signal W_{0,(2i+1)j} is determined by the combination of WE and COLⱼ and BLK₂ᵢ₊₁ and D. That is, W_{0,(2i+1)j} will be enabled (i.e., having a logic “1”) only when the Write Enable Signal (WE), the Column Selecting Address (COLⱼ) and the Block Selecting Signal (BLK₂ᵢ₊₁) are all enabled (i.e., having a logic “1”), and the Data to be Written into the MTJ (D) is logic “1”. For all other combinations, W_{0,(2i+1)j} will be disabled (i.e., having a logic “0”).

The Bidirectional Writing Control Signal W_{1b,(2i+1)j} is determined by the inverse of the combination of WE and COLⱼ and BLK₂ᵢ₊₁ and the inverse of D. That is, W_{1b,(2i+1)j} will be disabled (i.e., having a logic “1”) only when at least one of the Write Enable Signal (WE), the Column Selecting Address (COLⱼ), and the Block Selecting Signal (BLK₂ᵢ₊₁) are disabled (i.e., having a logic “0”) or the Data to be Written into the MTJ (D) is a logic “1”. Only when all of the Write Enable Signal (WE), the Column Selecting Address (COLⱼ), the Block Selecting Signal (BLK₂ᵢ₊₁) are enabled (i.e., having a logic “1”) and the Data to be Written into the MTJ (D) is a logic “0”), W_{1b,(2i+1)j} will be enabled (i.e., having a logic “0”).

The Bidirectional Writing Control Signal W_{0,(2i+2)j} is determined by the combination of WE and COLⱼ and BLK₂ᵢ₊₂ and the inverse of D. That is W_{0,(2i+2)j} will be enabled (i.e., having a logic “1”) only when the Write Enable Signal (WE), the Column Selecting Address (COLⱼ) and the Block Selecting Signal (BLK₂ᵢ₊₂) are all enabled (i.e., having a logic “1”), while the Data to be Written into the MTJ (D) is logic “0”. For all other combinations, W_{0,(2i+2)j} will be disabled (i.e., having a logic “0”).

The Bidirectional Writing Control Signal W_{1b,(2i+2)j} is determined by the inverse of the combination of WE and COLⱼ and BLK₂ᵢ₊₂ and D. That is, W_{1b,(2i+2)j} will be disabled (i.e., having a logic “1”) only when at least one of the Write Enable Signal (WE), the Column Selecting Address (COLⱼ), the Block Selecting Signal (BLK₂ᵢ₊₂) are disabled (i.e., having a logic “0”), or the Data to be Written into the MTJ (D) is logic “0”. Only when all of the Write Enable Signal (WE), the Column Selecting Address (COLⱼ), the Block Selecting Signal (BLK₂ᵢ₊₂) are enabled (i.e., having a logic “1”), and the Data to be Written into the MTJ (D) is logic “1”, W_{1b,(2i+2)j} will be enabled (i.e., having a logic “0”).

The total size of the block is given by the row number (1) in one sub-block by the total number of sub-blocks (m) by the total number of column (n).

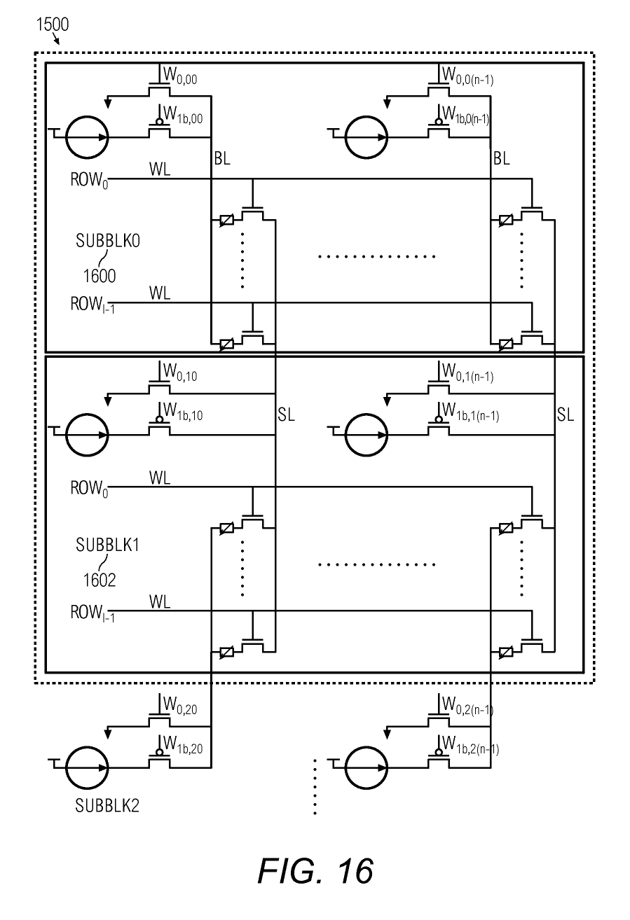

FIG. 16 shows an exemplary alternative design 1500 of FIG. 15 for sub-blocks 0, 1, and 2. In FIG. 16, each unit block will consist of two sub-blocks 1600, 1602. There are alternating rows of current sources with two different writing current amplitudes in this unit-block, with each row having the same amplitude.

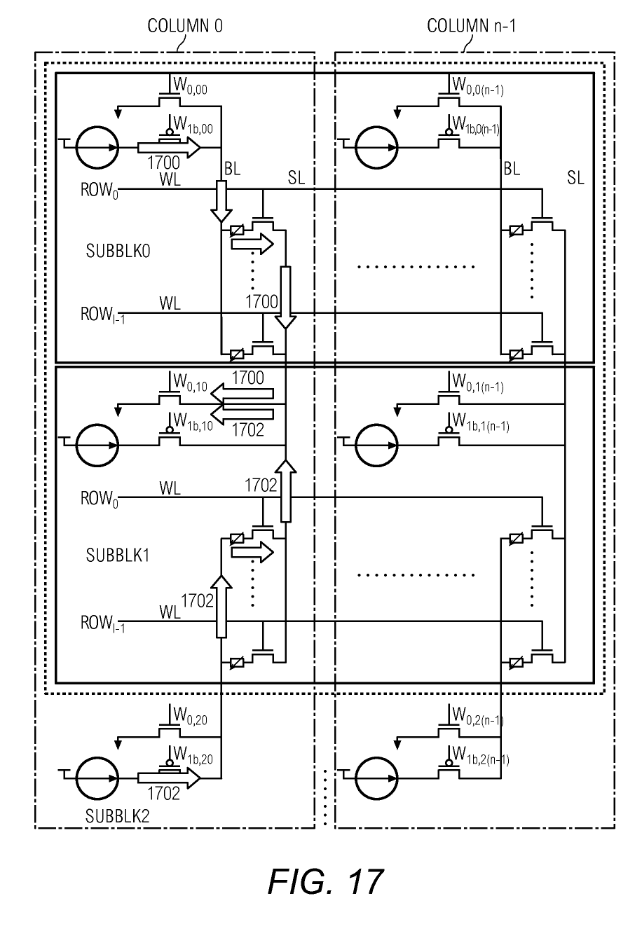

FIG. 17 shows an example of writing sequential of “1”s to two MTJ cells based on the pseudo code for the writing scheme for the exemplary circuit 1500 in FIG. 15.

In FIG. 17, to write a “1” to MTJ in sub-block 0 at row 0, column 0, transistors “W_{0,10}” and “W_{1b,10}” and the select transistor at row 0, column 0 are switched on while the other transistors are turned off. The current pulse flows from the top current source (at sub-block 0, column 0), into the MTJ and the ground (at sub-block 1, column 0) to close the writing path. Sequentially, to write a “1” to MTJ in sub-block 0 at row 0, column 0, the transistors “W_{0,10}” and “W_{1b,10}” and the select transistor at row 0, column 0 are switched on while the other transistors are turned off. The current pulse will flow from the top current source (at sub-block 2, column 0), into the MTJ and the ground (at sub-block 1, column 0) to close the writing path.

In other words, lines 1700 shows the writing of logic ‘1’ to sub-block 0 when W_{0,00}=0; W_{1b,00}=0; W_{0,10}=1; and W_{1b,10}=1. Lines 1702 shows the writing of logic ‘1’ to sub-block 1, when W_{0,10}=1; W_{1b,10}=1; W_{0,20}=0; and W_{1b,20}=0.

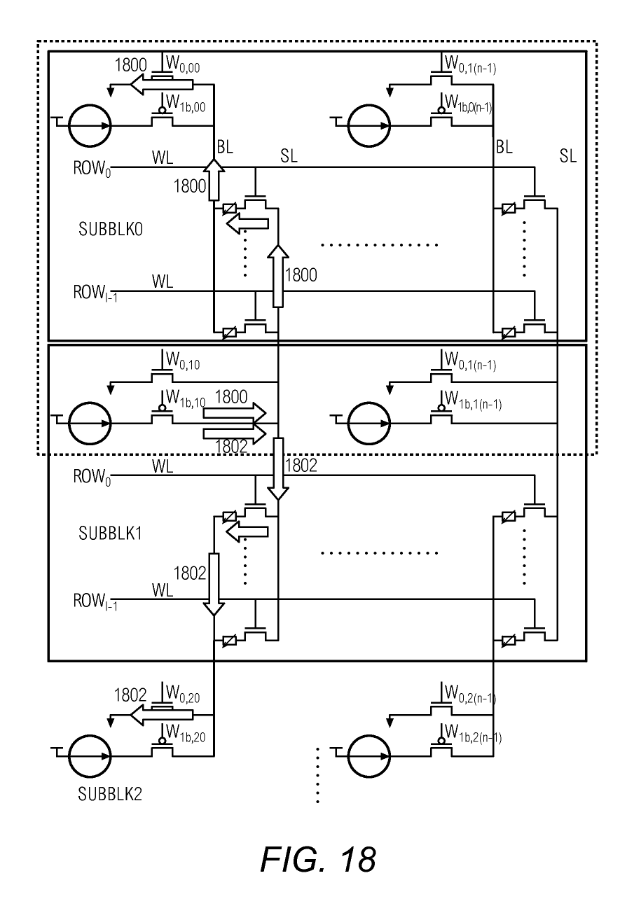

The same scheme applies to the writing of “0”, except an alternating set of current source is selected to complete the writing circuit. FIG. 18 shows an example of writing sequential of “0”s to two MTJ cells based on the pseudo code for the writing scheme for the exemplary circuit 1500 in FIG. 15.

In FIG. 18, lines 1800 shows the writing of logic ‘0’ to sub-block 0 when W_{0,00}=1; W_{1b,00}=1; W_{0,10}=0; and W_{1b,10}=0. Lines 1802 shows the writing of logic ‘0’ to sub-block 1, when W_{0,10}=0; W_{1b,10}=0; W_{0,20}=1; and W_{1b,20}=1.

Sub-block 0 and sub-block 1 share the current source and column address at the middle as seen in FIGS. 17 and 18.

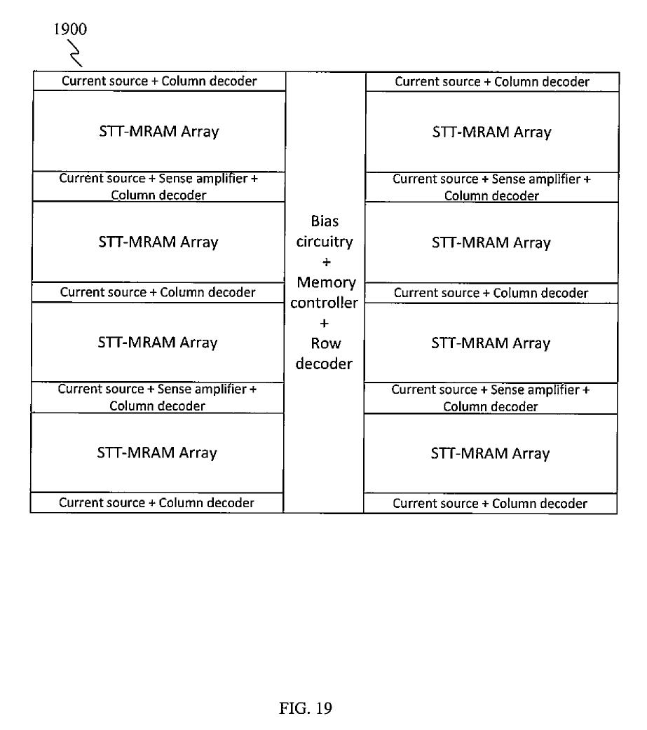

FIG. 19 shows a top level floor plan of an exemplary memory bank 1900. The memory controller and bias circuitry are placed in the middle of the memory bank. At the left side and the right side of the memory controller there are multiple sub memory blocks. Though there are four sub-blocks at both sides in this example, the design may also be implemented for other number of sub-blocks. For a given bank size, more number of sub-blocks leads to higher speed but suffers from larger area. Each STT-MRAM array has current source and column decoder at top side and bottom side. The current source, column decoder may be shared between two adjacent STT-MRAM arrays to reduce the area. The sense amplifier and reading circuitry may be shared by every two adjacent memory arrays.

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

We claim:

1. A current writing circuit for a resistive memory cell arrangement, the resistive memory cell arrangement having a plurality of resistive memory cells, the current writing circuit comprising:
a first current source;
a first reference potential terminal;
a first switch configured to switch between the first current source and the first reference potential terminal during a write operation;
a second current source;
a second reference potential terminal; and
a second switch configured to switch between the second reference potential terminal when the first switch is switched to the first current source, and the second current source when the first switch is switched to the first reference potential terminal, during the write operation;
wherein the first current source and the second current source are of the same polarity.

2. The current writing circuit as claimed in claim 1, wherein the first current source has a current amplitude the same as that of the second current source.

3. The current writing circuit as claimed in claim 1, wherein the first current source has a current amplitude different from that of the second current source.

4. The current writing circuit as claimed in claim 1, wherein the first current source and the second current source are positive current sources.

5. The current writing circuit as claimed in claim 1, wherein the first reference potential terminal and the second reference potential terminal, each comprises a ground potential or 0 V.

6. The current writing circuit as claimed in claim 1, further comprising a third switch configured to control the write operation to the memory cell.

7. The current writing circuit as claimed in claim 6, wherein the third switch is controllable by a word line of the resistive memory cell arrangement.

8. The current writing circuit as claimed in claim 6, wherein the third switch is configured to couple in series with the memory cell between a bit line and a source line, and to switch between a low impedance to enable the write operation and a high impedance to disable the write operation.

9. The current writing circuit as claimed in claim 1, wherein the first switch comprises a pair of transistors respectively comprising a source terminal, a drain terminal and a gate terminal.

10. The current writing circuit as claimed in claim 9, wherein for the first switch, the drain terminals of the transistors are configured to couple to a bit line, the source terminal of one of the transistors is coupled to the first reference potential terminal, and the source terminal of the other of the transistors is coupled to the first current source.

11. The current writing circuit as claimed in claim 1, wherein the second switch comprises a pair of transistors respectively comprising a source terminal, a drain terminal and a gate terminal.

12. The current writing circuit as claimed in claim 11, wherein for the second switch, the drain terminals of the transistors are configured to couple to a source line, the source terminal of one of the transistors is coupled to the second reference potential terminal, and the source terminal of the other of the transistors is coupled to the second current source.

13. The current writing circuit as claimed in claim 9, wherein the pair of transistors comprises two CMOS transistors.

14. The current writing circuit as claimed in claim 11, wherein the pair of transistors comprises two CMOS transistors.

15. The current writing circuit as claimed in claim 1, wherein the current writing circuit comprises a plurality of first switches and second switches configured to respectively couple to a plurality of bit lines and source lines.

16. A memory cell arrangement, comprising:
a plurality of resistive memory cells; and
a current writing circuit for the plurality of resistive memory cells, the current writing circuit comprising:
a first current source;
a first reference potential terminal;
a first switch configured to switch between the first current source and the first reference potential terminal during a write operation;
a second current source;
a second reference potential terminal; and
a second switch configured to switch between the second reference potential terminal when the first switch is switched to the first current source, and the second current source when the first switch is switched to the first reference potential terminal, during the write operation;
wherein the first current source and the second current source are of the same polarity.

17. The memory cell arrangement as claimed in claim 16, wherein the resistive memory cells comprise magnetoresistive memory cells.

18. The memory cell arrangement as claimed in claim 17, wherein the magnetoresistive memory cells comprise a spin transfer torque magnetoresistive random access memory.

19. A method of writing into a target resistive memory cell of a resistive memory cell arrangement, the method comprising:
switching between a first current source and a first reference potential terminal to a bit line during a write operation; and
switching between a second reference potential terminal when the first current source is coupled to the bit line, and a second current source when the first reference potential terminal is coupled to the bit line, to a source line during the write operation;
wherein the first current source and the second current source are of the same polarity.

20. The method as claimed in claim 19, further comprising controlling the write operation to the resistive memory cell by a word line of the resistive memory cell arrangement.

21. The method as claimed in claim 19, wherein the resistive memory cell arrangement comprises a plurality of resistive memory cells, and wherein writing into each target resistive memory cell is performed sequentially.

22. An address decoder and memory controller for controlling a current writing circuit for writing into a target resistive memory cell of a resistive memory cell arrangement, wherein the current writing circuit comprises:
a first current source;
a first reference potential terminal;
a first switch configured to switch between the first current source and the first reference potential terminal during a write operation;
a second current source;
a second reference potential terminal; and
a second switch configured to switch between the second reference potential terminal when the first switch is switched to the first current source, and the second current source when the first switch is switched to the first reference potential terminal, during the write operation;
wherein the first current source and the second current source are of the same polarity.
